(19) United States
(12) Patent Application Publication
(10) Pub. No.: US 2026/0173966 A1
(43) Pub. Date: Jun. 18, 2026

(54) SEMICONDUCTOR PACKAGE

(71) Applicant: Samsung Electronics Co., Ltd., Suwon-si (KR)

(72) Inventors: Huiyeong Jang, Suwon-si (KR); Jaejun Lee, Suwon-si (KR); Juhyeon Kim, Suwon-si (KR)

(21) Appl. No.: 19/284,828

(22) Filed: Jul. 30, 2025

(30) Foreign Application Priority Data
Dec. 12, 2024 (KR) 10-2024-0185079

(51) Int. Cl. H10W 90/00; H10B 80/00; H10W 20/20; H10W 72/90

(52) U.S. Cl. CPC H10W 90/00; H10B 80/00; H10W 20/20; H10W 72/944; H10W 72/9445; H10W 90/722; H10W 90/792

(57) ABSTRACT

A semiconductor package design includes reducing the thickness of a base chip and the total thickness of a package, designing a fine pitch, and reducing a heterogeneous interface region. The semiconductor package includes a logic chip, a first memory chip arranged on the logic chip with a size less than that of the logic chip and stacked on the logic chip through hybrid copper bonding, and at least one second memory chip stacked on the first memory chip.

### CROSS-REFERENCE TO RELATED APPLICATION

This application is based on and claims priority under 35 U.S.C. § 119 to Korean Patent Application No. 10-2024-0185079, filed on December 12, 2024, in the Korean Intellectual Property Office, the disclosure of which is incorporated by reference herein in its entirety.

### BACKGROUND

The rapid development of the electronics industry and user demands, electronic devices are becoming smaller and lighter. As electronic devices become smaller and lighter, semiconductor packages used therein are also becoming smaller and lighter, and high reliability along with high performance and large capacity is desired.

### SUMMARY

The present disclosure relates to a semiconductor package with reduced thickness of a base chip and the total thickness of a package, a fine pitch, and a reduced heterogeneous interface region.

According to an aspect of the present disclosure, there is provided a semiconductor package including a logic chip, a first memory chip arranged on the logic chip with a size less than that of the logic chip and stacked on the logic chip through hybrid copper bonding (HCB), and at least one second memory chip stacked on the first memory chip.

According to another aspect of the present disclosure, a semiconductor package includes a first semiconductor chip including a first chip pad, a second semiconductor chip including a second chip pad, having a smaller size than the first semiconductor chip, stacked on the first semiconductor chip, and having the second chip pad coupled to the first chip pad through HCB, and a third semiconductor chip including a third chip pad and stacked on the second semiconductor chip through a connection terminal arranged on the third chip pad. A pitch of the second chip pad is less than a pitch of the third chip pad.

According to another aspect of the present disclosure, there is provided a semiconductor package including a base chip including a first chip pad and a first protective layer, a first semiconductor chip including a second chip pad and a second protective layer and stacked on the base chip with a size smaller than that of the base chip, and a second semiconductor chip including a third chip pad and stacked on the first semiconductor chip through a connection terminal with substantially the same size as the first semiconductor chip. The first chip pad and the first protective layer are coupled to the second chip pad and the second protective layer through HCB, and the second chip pad has a smaller pitch than the third chip pad.

### BRIEF DESCRIPTION OF THE DRAWINGS

Implementations will be more clearly understood from the following detailed description taken in conjunction with the accompanying drawings.

FIG. 1A is a cross-sectional view of a semiconductor package according to an implementation. FIG. 1B is an enlarged cross-sectional view of portion A of FIG. 1A.

FIGS. 2A and 2B are cross-sectional views illustrating a comparison between a thickness and a signal path of a semiconductor package of a comparative example and a thickness and a signal path of a semiconductor package of an implementation.

FIGS. 3A, 3B, and 3C illustrate scanning acoustic tomography (SAT) photographs illustrating a result of reliability evaluation of a semiconductor package of an implementation.

FIG. 4 is a cross-sectional view of semiconductor package according to some implementations.

FIG. 5 is a cross-sectional view of a semiconductor package according to some implementations.

FIGS. 6A, 6B, and 6C are cross-sectional views of semiconductor packages according to some implementations.

FIGS. 7A, 7B, and 7C are cross-sectional views illustrating the structure of the semiconductor device in the semiconductor package of FIG. 6C in more detail.

FIGS. 8A and 8B are cross-sectional views of semiconductor packages according to some implementations.

FIGS. 9A, 9B, 9C, 9D, and 9E are cross-sectional views schematically illustrating processes of a semiconductor package manufacturing method according to some implementations.

### DETAILED DESCRIPTION

Hereinafter, implementations of the disclosure will be described in detail with reference to the accompanying drawings. Like reference numerals refer to like elements, and their repetitive descriptions are omitted.

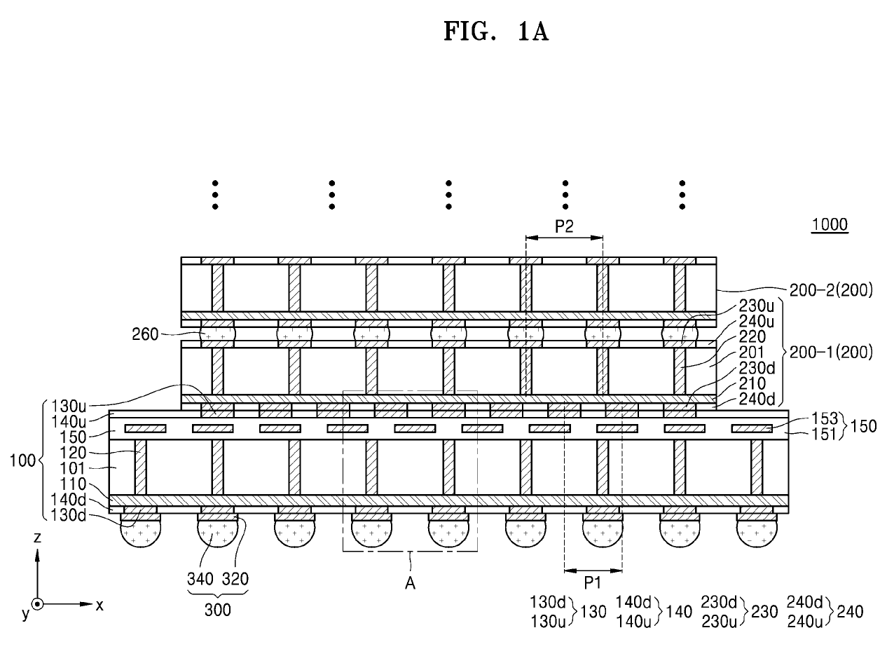

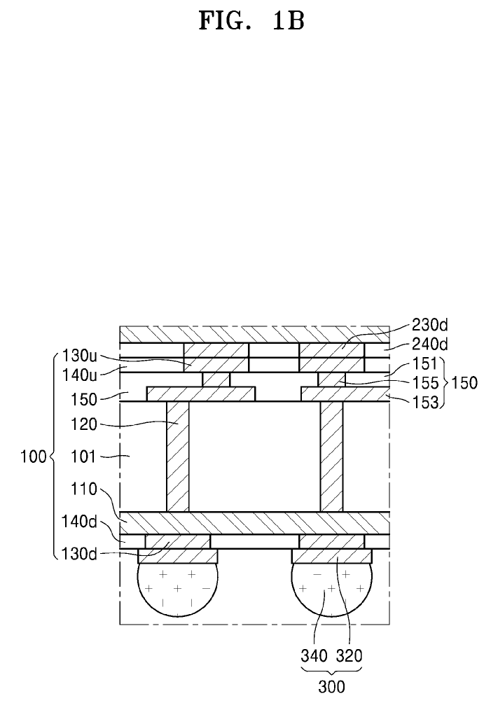

FIG. 1A is a cross-sectional view of a semiconductor package according to an implementation. FIG. 1B is an enlarged cross-sectional view of portion A of FIG. 1A.

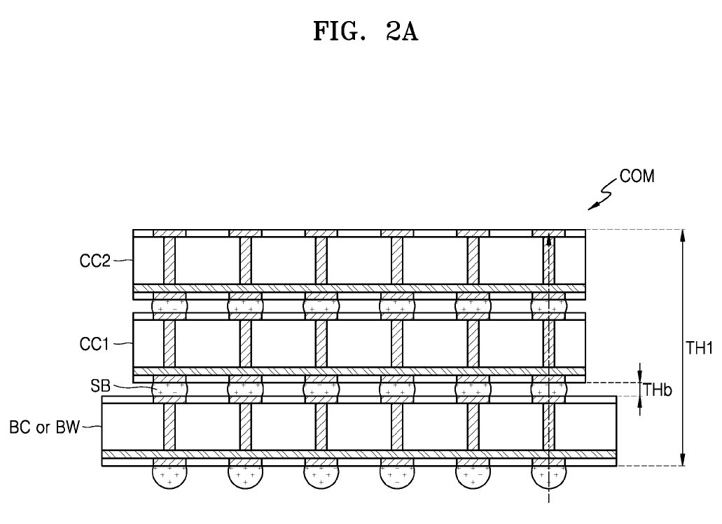

FIGS. 2A and 2B are cross-sectional views illustrating a comparison between a thickness and a signal path of a semiconductor package of a comparative example and a thickness and a signal path of a semiconductor package of an implementation.

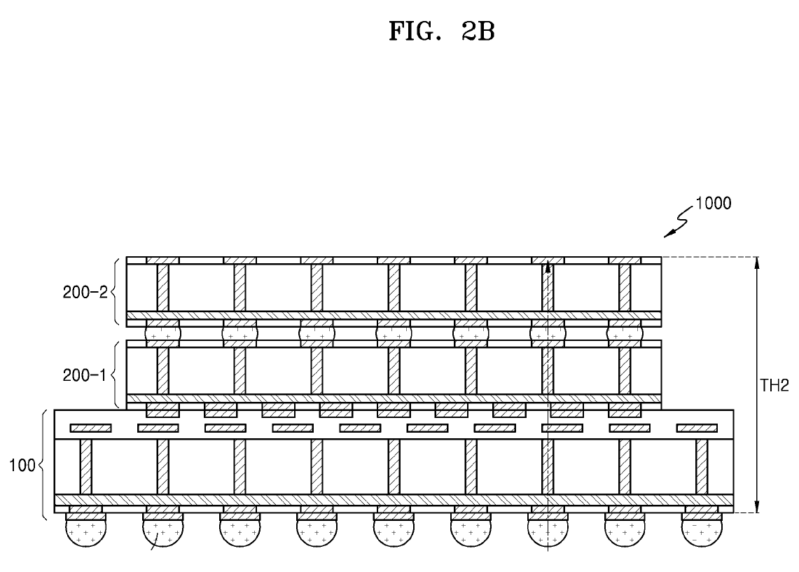

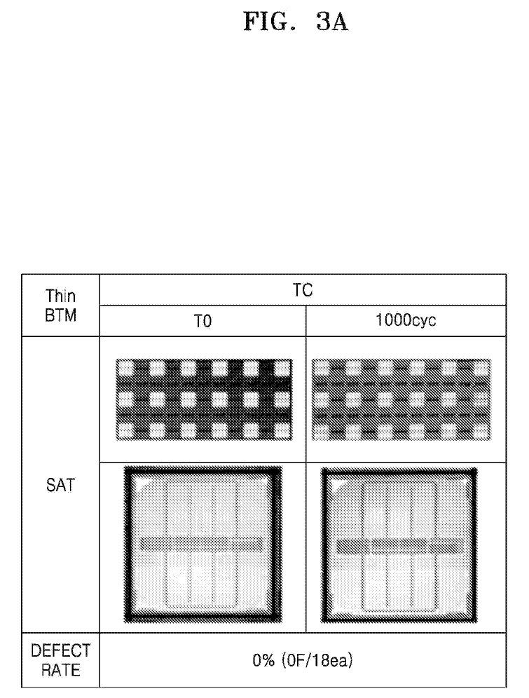

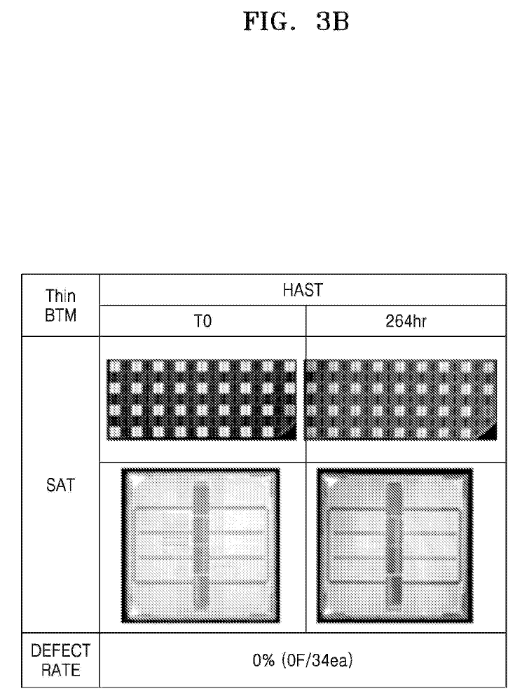

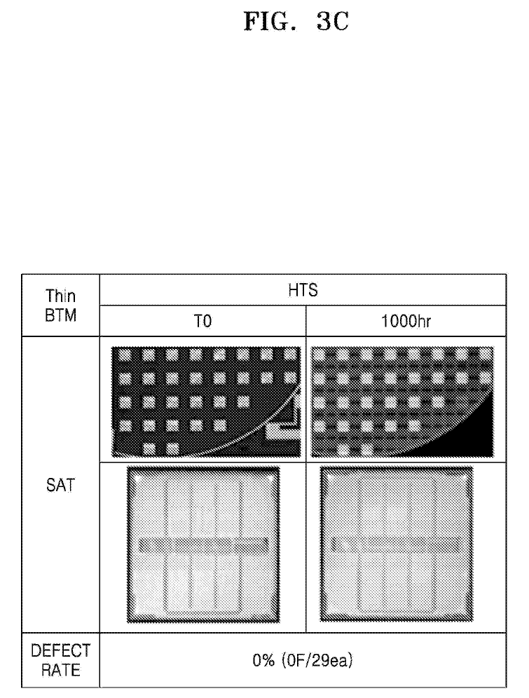

FIGS. 3A, 3B, and 3C illustrate scanning acoustic tomography (SAT) photographs illustrating a result of reliability evaluation of a semiconductor package of an implementation.

Referring to FIGS. 1A to 3C, a semiconductor package 1000 of an implementation may include a base chip 100, memory chips 200, and external connection terminals 300. The semiconductor package 1000 of an implementation may include, for example, a high bandwidth memory (HBM) package. However, the semiconductor package 1000 of an implementation is not limited to the HBM package.

The base chip 100 may include a first body layer 101, a first active layer 110, a first through electrode 120, a first pad 130, a first protective layer 140, and a first redistribution layer 150. As illustrated in FIG. 1A, the base chip 100 may be larger in size than each of the memory chips 200 arranged thereon. However, the size of the base chip 100 is not limited thereto. For example, in some implementations, the base chip 100 may have substantially the same size as each of the memory chips 200.

The first body layer 101 may include, for example, a semiconductor element such as silicon (Si) or germanium (Ge). In addition, the first body layer 101 may include a compound semiconductor such as silicon carbide (SiC), gallium arsenide (GaAs), indium arsenide (InAs), or indium phosphide (InP). The first body layer 101 may have a silicon on insulator (SOI) structure. For example, the first body layer 101 may include a buried oxide (BOX) layer. The first body layer 101 may include a conductive region, for example, a structure such as a well doped with an impurity or a source/drain region doped with an impurity. The first body layer 101 may include various device isolation structures such as a shallow trench isolation (STI) structure.

The first active layer 110 may include an integrated circuit layer and a wiring layer on the integrated circuit layer. The integrated circuit layer may include various types of devices. For example, the integrated circuit layer may include various active and/or passive elements such as transistors, memory devices, logic elements, system large scale integration (LSI), a CMOS imaging sensor (CIS), and a micro-electro-mechanical system (MEMS).

The transistor may include, for example, a bipolar junction transistor (BJT), or a field effect transistor (FET) such as a planar FET or a FinFET. The memory devices may include, for example, volatile memory devices such as dynamic random access memory (DRAM) or static random access memory (SRAM), or non-volatile memory devices such as flash memory, phase-change random access memory (PRAM), magnetoresistive random access memory (MRAM), ferroelectric random access memory (FeRAM), or resistive random access memory (RRAM).

Logic elements may include, for example, an AND, a NAND, an OR, NOR, an exclusive OR (XOR), an exclusive NOR (XNOR), an inverter INV, an adder ADD, a delay DLY, a filter FIL, a multiplexer (MXT/MXIT), an OR/AND/INVERTER (OAI), an AND/OR (AO), AND/OR/INVERTER (AOI), a D flip-flop, a reset flip-flop, a master-slave flip-flop, a latch, a counter, or buffer elements. Logic elements may perform various signal processing such as analog signal processing, analog-to-digital (A/D) conversion, and control.

The wiring layer may connect at least two elements to each other, may connect the elements to a conductive region of the first body layer 101, or may connect the elements to the first pad 130, for example, a first lower pad 130d. In addition, the wiring layer may connect the first through electrode 120 to the first lower pad 130d. The wiring layer may include, for example, a wiring insulation layer, wirings, and contacts or vias. In the semiconductor package 1000 of some implementations, the first active layer 110 may be arranged under the first body layer 101 and the first through electrode 120.

In the semiconductor package 1000 of some implementations, the base chip 100 may include a plurality of logic elements in the integrated circuit layer of the first active layer 110. The base chip 100 may be arranged under the memory chips 200, may integrate signals from the memory chips 200 to transmit the signals to the outside, and may transmit signals and power from the outside to the memory chips 200. Accordingly, the base chip 100 may be referred to as a buffer chip or an interface chip.

In some implementations, the base chip 100 may include a controller controlling signal transmission between the memory chips 200 and an external device. When the base chip 100 includes a controller, the base chip 100 may be referred to as a logic chip or a control chip. In some implementations, the base chip 100 may include logic elements for operation. In addition, the base chip 100 may include a power management integrated circuit (PMIC) managing power or clocks. For reference, when the base chip 100 is referred to as a buffer chip, the memory chips 200 may be referred to as core chips.

In the semiconductor package 1000 of some implementations, the base chip 100 is not limited to the buffer chip or the logic chip. For example, the base chip 100 may include a plurality of memory devices in the integrated circuit layer of the first active layer 110. Accordingly, the base chip 100 may include a memory chip.

The first through electrode 120 may extend from a top surface of the first body layer 101 to a bottom surface of the first body layer 101 through the first body layer 101. In some implementations, the first through electrode 120 may extend to the inside of the first active layer 110. In the semiconductor package 1000 of some implementations, the first body layer 101 may include Si, and thus the first through electrode 120 may correspond to a through silicon via (TSV).

The first through electrode 120 may have a pillar shape and may include a barrier film on an outer surface and a buried conductive layer on the inside. The barrier film may include at least one material selected from titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boride (NiB). The buried conductive layer may include at least one material selected from copper (Cu) alloys such as Cu, CuSn, CuMg, CuNi, CuZn, CuPd, CuAu, CuRe, and CuW, W, a W alloy, Ni, Ru, and Co. An insulating layer may be between the first through electrode 120 and the first body layer 101, or between the first through electrode 120 and the first active layer 110. The insulating layer may include, for example, an oxide film, a nitride film, a carbide film, a polymer, or a combination thereof.

The first pad 130 may include a first upper pad 130u and a first lower pad 130d. The first upper pad 130u may be arranged on a top surface of the first redistribution layer 150. The first upper pad 130u may be connected to the first through electrode 120 through a first redistribution line 153 of the first redistribution layer 150. The first upper pad 130u may be bonded to a second lower pad 230d of a first memory chip 200-1 through hybrid copper bonding (HCB). HCB will be described in more detail below in the description of connection between the base chip 100 and the first memory chip 200-1.

The first lower pad 130d may be arranged on a bottom surface of the first active layer 110 and may be connected to the wirings of the wiring layer of the first active layer 110. The first lower pad 130d may be connected to the first through electrode 120 through the wiring layer.

The first pad 130 may include at least one of, for example, aluminum (Al), Cu, Ni, W, platinum (Pt), and gold (Au). In the semiconductor package 1000 of some implementations, the first pad 130 of the base chip 100 may include Cu. However, the material of the first pad 130 is not limited to Cu.

The first protective layer 140 may be arranged on bottom and top surfaces of the base chip 100. For example, the first protective layer 140 may include a first upper protective layer 140u and a first lower protective layer 140d. The first upper protective layer 140u may be arranged on the top surface of the first redistribution layer 150. The first upper pad 130u may be arranged through at least part of the first upper protective layer 140u. For example, the first upper pad 130u may be connected to the first redistribution line 153 of the first redistribution layer 150 through at least part of the first upper protective layer 140u.

In addition, the first upper protective layer 140u may reduce a step between the first redistribution line 153 of the first redistribution layer 150 or the first upper pad 130u and a top surface of the first redistribution body layer 151. Accordingly, the first upper protective layer 140u may contribute to flattening the top surface of the first redistribution layer 150. In addition, regions on the top surface of the first redistribution layer 150 that does not overlap with an external region of the first memory chip 200-1 is referred to as an overhang region. When the first redistribution line 153 is not formed in the overhang region, the above-described step problem may increase. However, by providing the first upper protective layer 140u, the step problem in the overhang region may be solved. In some implementations, the first upper protective layer 140u may be referred to as a redistribution layer (RDL) buffer coating (RBC) layer.

The first lower protective layer 140d may be arranged on the bottom surface of the first active layer 110. The first lower pad 130d may be arranged through at least part of the first lower protective layer 140d. For example, a thick pad metal layer may be arranged in the first lower protective layer 140d, and the first lower pad 130d may be connected to the pad metal layer through part of the first lower protective layer 140d. The pad metal layer may include, for example, Al. Therefore, the first lower pad 130d may be connected to the wirings of the wiring layer through the pad metal layer. In addition, the first lower pad 130d may be connected to the first through electrode 120 through the wiring layer.

The first protective layer 140 may include, for example, an oxide film, a nitride film, a carbide film, a polymer, or a combination thereof. However, the material of the first protective layer 140 is not limited thereto. The first protective layer 140 may have a single-film or multi-film structure.

The first redistribution layer 150 may be arranged on the first body layer 101. The first redistribution layer 150 may include a first redistribution body layer 151 and the first redistribution line 153. The first redistribution body layer 151 may include an insulating material, for example, a photo imageable dielectric (PID) or a photo imageable polyimide (PIP) resin, and may further include an inorganic filler. However, the material of the first redistribution body layer 151 is not limited to the above-described material. For example, the first redistribution body layer 151 may include a polyimide isoindro quirazorindione (PIQ), a polyimide (PI), or polybenzoxazole (PBO).

The first redistribution body layer 151 may have a multi-layer structure according to the multi-layer structure of the first redistribution line 153. However, in FIGS. 1A and 1B, for example, the first redistribution body layer 151 is illustrated as a single-layer structure. When the first redistribution body layer 151 has a multi-layer structure, all layers of the first redistribution body layer 151 may include the same material, or at least one layer may include a different material.

The first redistribution line 153 may be arranged in a single-layer or multi-layer structure in the first redistribution body layer 151. When the first redistribution line 153 is arranged in a multi-layer structure, the first redistribution lines 153 arranged in different layers may be connected to one another through a via 155, as shown in FIG. 1B. The first redistribution line 153 and the via 155 may include, for example, Cu. However, the material of the first redistribution line 153 and the via 155 is not limited to Cu.

As described above, the first upper pad 130u may be arranged on an upper side of the first redistribution line 153. In addition, the first upper protective layer 140u may cover the first redistribution body layer 151. The first upper pad 130u may be buried in the first upper protective layer 140u. The first upper pad 130u may be connected to the first redistribution line 153 through the via 155. In some implementations, the first upper pad 130u may be included as part of the first redistribution line 153. A bottom surface of the first redistribution body layer 151 may be in contact with the top surface of the first body layer 101. In addition, the first redistribution line 153 may be connected to the first through electrode 120. In some implementations, at least one insulating layer such as a silicon nitride layer may be arranged between the first redistribution body layer 151 and the first body layer 101. In addition, in some implementations, a through electrode pad may be arranged on the top surface of the first through electrode 120, and the first through electrode 120 may be connected to the first redistribution line 153 through the through electrode pad. In some implementations, the through electrode pad may be included as part of the first redistribution line 153.

In the base chip 100 of the semiconductor package 1000 of some implementations, the first redistribution layer 150 is arranged on the first body layer 101 so that the first through electrode 120 may be arranged without being restricted by a position of the first upper pad 130u. Accordingly, as illustrated in FIG. 1A, the first through electrode 120 may be arranged in the first body layer 101 with a pitch greater than that of the first upper pad 130u. In addition, the first through electrode 120 may be arranged on an outer portion of the first body layer 101 corresponding to the outside of the memory chip 200 by the first redistribution layer 150. Although it is illustrated in FIG. 1A that a pitch of a second through electrode 220 of the memory chip 200 is equal to the pitch of the first through electrode 120 of the base chip 100, the pitch of the second through electrode 220 may be different from the pitch of the first through electrode 120.

The memory chips 200 may be stacked on the base chip 100. In the semiconductor package 1000 of some implementations, for example, 12 memory chips 200 may be stacked on the base chip 100. However, the number of memory chips 200 stacked on the base chip 100 is not limited to 12. For example, 2 to 11, or 13 or more memory chips 200 may be stacked on the base chip 100.

In the semiconductor package 1000 of some implementations, the number of memory chips 200 may be, for example, 4n (n is a natural number). Accordingly, the semiconductor package 1000 may include a multiple of 4 memory chips 200, such as 4, 8, or 12. In addition, four memory chips 200 may be tested and operated together with the same stack-ID. For example, when the semiconductor package 1000 includes 12 memory chips 200, the first to fourth memory chips may have a first stack-ID, the fifth to eighth memory chips may have a second stack-ID, and the ninth to twelfth memory chips may have a third stack-ID. However, the semiconductor package 1000 is not limited to the memory chip 200 in multiples of 4 and the corresponding stack-ID. For example, the semiconductor package 1000 may include a multiple of 2 memory chips 200 and a corresponding stack-ID, or may include a multiple of 8 memory chips 200 and a corresponding stack-ID.

The plurality of memory chips 200 may have substantially the same horizontal size and internal structure. However, the uppermost memory chip 200 may not include a through electrode. In addition, the uppermost memory chip 200 may be thicker than the other memory chips 200. In some implementations, the thickness of the uppermost memory chip 200 may be adjusted so that the total height of the semiconductor package 1000 may be adjusted. Hereinafter, a specific structure of the memory chip 200 will be described by using the first memory chip 200-1 as an example.

The first memory chip 200-1 may include a second body layer 201, a second active layer 210, a second through electrode 220, a second pad 230, and a second protective layer 240. The second body layer 201 is the same as described for the first body layer 101 of the base chip 100.

The second active layer 210 may include a plurality of memory devices in an integrated element layer. For example, the second active layer 210 may include volatile memory devices such as DRAM or SRAM, or non-volatile memory devices such as PRAM, MRAM, FeRAM, or RRAM. For example, the first memory chip 200-1 may include DRAM devices in the second active layer 210. Accordingly, the first memory chip 200-1 may include a DRAM chip. In addition, as described above, the semiconductor package 1000 may include an HBM package, and the first memory chip 200-1 may include a DRAM chip for HBM.

The second through electrode 220 may pass through the second body layer 201. In addition, the second through electrode 220 may extend into the second active layer 210. For example, the first memory chip 200-1 may be divided into a cell region and a pad region, the second through electrode 220 may be formed in the pad region, and the second through electrode 220 may extend into the second active layer 210 through the second body layer 201. Other details about the second through electrode 220 are the same as those described about the first through electrode 120 of the base chip 100.

The second pad 230 may include a second lower pad 230d arranged on a bottom surface of the second active layer 210 and a second upper pad 230u arranged on a top surface of the second body layer 201. The second lower pad 230d may be connected to wirings of a wiring layer of the second active layer 210 on the bottom surface of the second active layer 210. In addition, the second lower pad 230d may be connected to the second through electrode 220 through the wiring layer. The second upper pad 230u may be connected to the second through electrode 220 on the top surface of the second body layer 201. The material of the second pad 230 is the same as described for the first pad 130 of the base chip 100.

The second protective layer 240 may include a second lower protective layer 240d arranged on the bottom surface of the second active layer 210 and a second upper protective layer 240u arranged on the top surface of the second body layer 201. The second protective layer 240 is the same as described for the first protective layer 140 of the base chip 100.

The second upper pad 230u may be arranged through at least a part of the second upper protective layer 240u. For example, the second upper pad 230u may be connected to the second through electrode 220 through at least a part of the second upper protective layer 240u. The second lower pad 230d may be arranged through at least a part of the second lower protective layer 240d. For example, the second lower pad 230d may be connected to a pad metal layer through part of the second lower protective layer 240d and may be connected to the wirings of the wiring layer through the pad metal layer. In addition, the second lower pad 230d may be connected to the second through electrode 220 through the wiring layer.

The external connection terminals 300 may be arranged on a bottom surface of the base chip 100. Each of the external connection terminals 300 may include a pillar 320 and a solder 340. The pillar 320 may include, for example, Ni, Cu, palladium (Pd), Pt, Au, or a combination thereof. In some implementations, the pillar 320 may serve as a pad and may include Cu. Accordingly, the pillar 320 may be referred to as a bump pad, a Cu-pad, or a Cu-pillar. When the pillar 320 serves as the pad, a separate pad may not be formed on the bottom surface of the base chip 100. In some implementations, the pillar 320 may be omitted.

The solder 340 may be arranged on the pillar 320. The solder 340 may include tin (Sn), indium (In), bismuth (Bi), antimony (Sb), Cu, silver (Ag), zinc (Zn), and/or an alloy thereof. For example, the solder 340 may include Sn, Sn-Ag, Sn-Au, Sn-Cu, Sn-Bi, Sn-Zn, Sn-Ag-Cu, Sn-Ag-Bi, Sn-Ag-Zn, Sn-Cu-Bi, Sn-Cu-Zn, Sn-Bi-Zn, or any combination thereof. In some implementations, the solder 340 may be referred to as a bump or a solder bump.

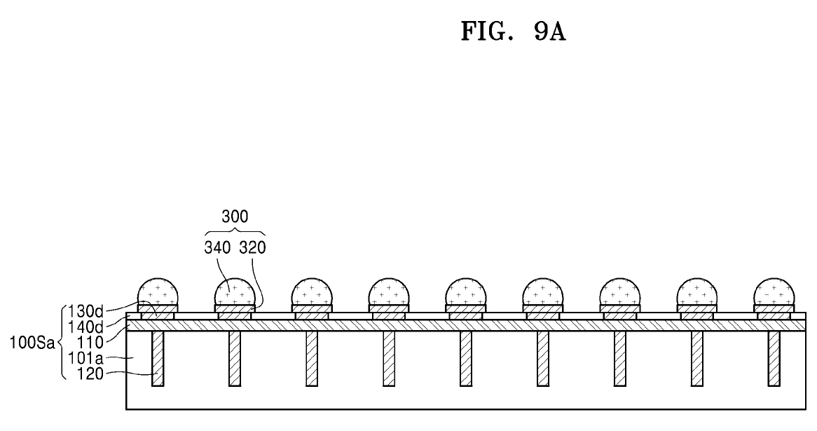

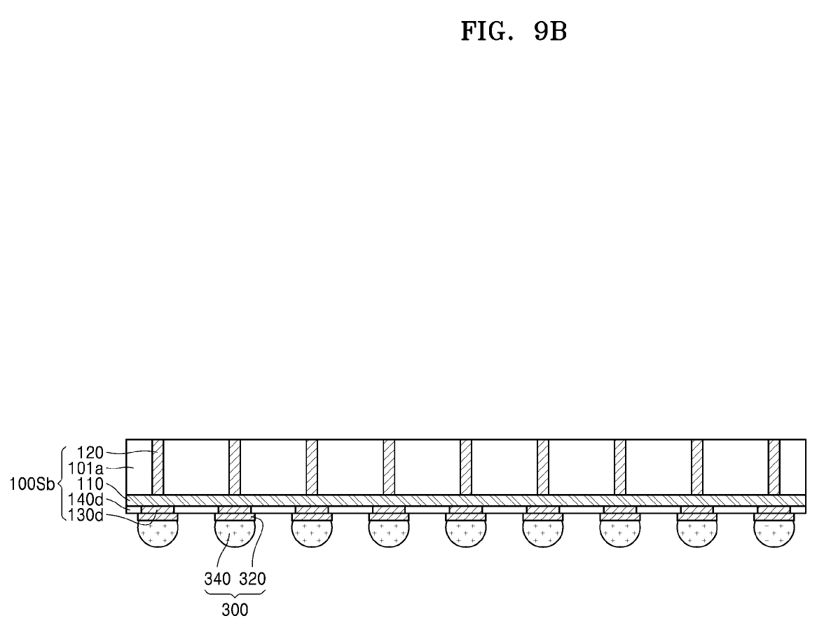

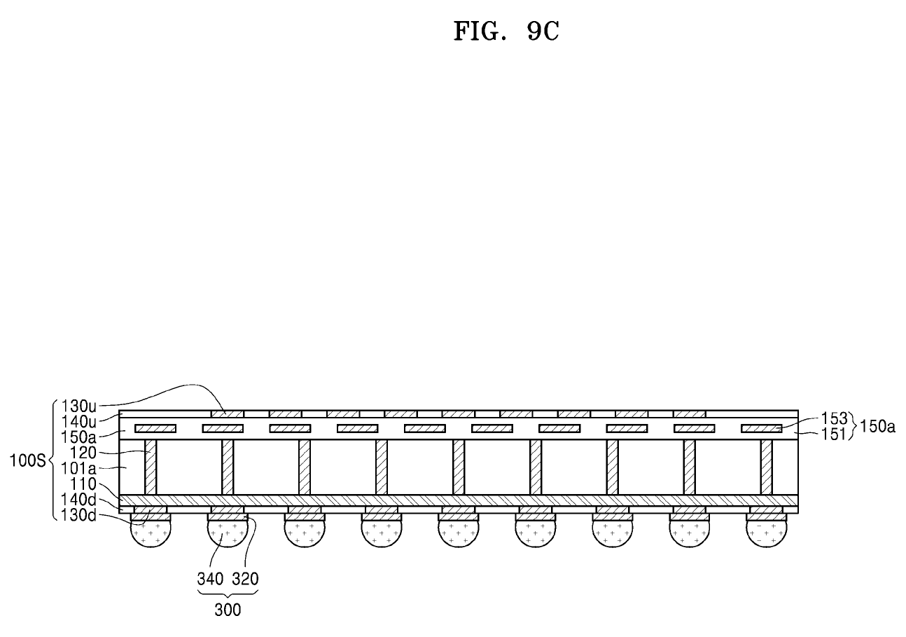

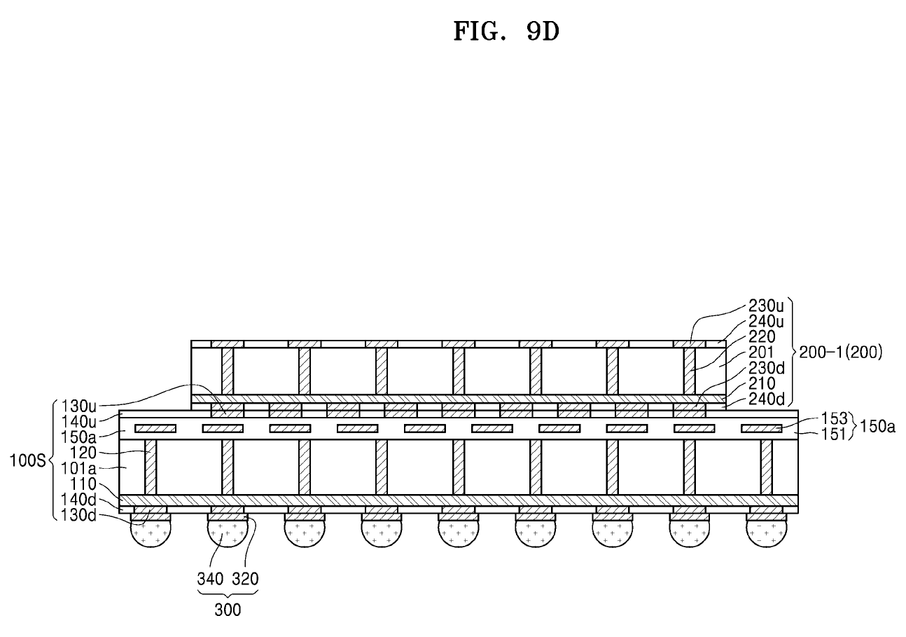

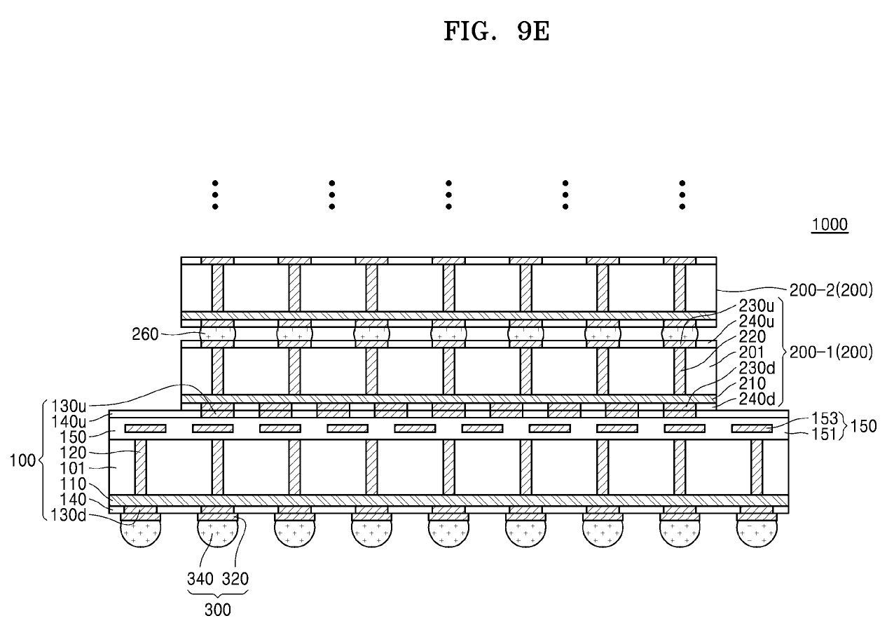

In the semiconductor package 1000 of some implementations, the first memory chip 200-1 may be stacked on the base chip 100 through HCB. HCB may refer to bonding that is a combination of pad-to-pad bonding and insulator-to-insulator bonding. Because the pad usually includes Cu, pad-to-pad bonding is also called Cu-to-Cu bonding. Specifically, the first upper pad 130u of the base chip 100 may be coupled to the corresponding second lower pad 230d of the first memory chip 200-1, and the first upper protective layer 140u of the base chip 100 may be coupled to the second lower protective layer 240d of the first memory chip 200-1, thereby forming HCB between the base chip 100 and the first memory chip 200-1. HCB will be described in more detail in description of the semiconductor package manufacturing method of FIGS. 9A, 9B, 9C, and 9D.

Moreover, in the semiconductor package 1000 of some implementations, the memory chips 200 above the first memory chip 200-1 among the memory chips 200 may be stacked on the memory chip 200 immediately below through first connection terminals 260. For example, a second memory chip 200-2 may be stacked on the first memory chip 200-1 through the first connection terminals 260. Accordingly, the first connection terminal 260 may be arranged between the second upper pad 230u of the first memory chip 200-1 and the second lower pad 230d of the second memory chip 200-2.

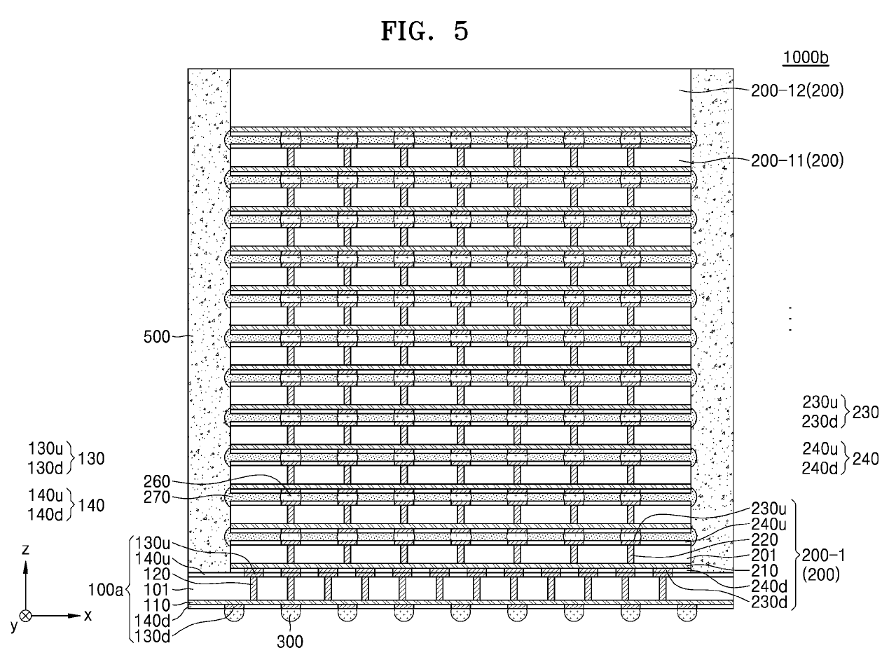

As the memory chips 200 above the first memory chip 200-1 are stacked on the memory chip 200 immediately below through the first connection terminals 260, an adhesive layer (refer to 270 of FIG. 5) may be arranged between adjacent memory chips 200. For example, the adhesive layer 270 may fill a space between the adjacent memory chips 200 and may cover side surfaces of the first connection terminals 260. The adhesive layer 270 may include, for example, a non-conductive film (NCF). The NCF may generally be used as an adhesive layer when bonding semiconductor chips by a thermal compression bonding (TCB) method in a semiconductor chip stacking process. However, in the semiconductor package 1000 of some implementations, the material of the adhesive layer 270 is not limited to the NCF. In addition, in some implementations, an underfill material may be filled between adjacent memory chips 200 instead of the adhesive layer 270. In FIG. 1A, the adhesive layer 270 is not shown for convenience.

In the semiconductor package 1000 of some implementations, the memory chips 200 above the first memory chip 200-1 are not limited to a stacked structure through the first connection terminals 260, and may be stacked on the memory chip 200 immediately below through HCB. In this case, the adhesive layer 270 may be omitted.

Although not shown, in the semiconductor package 1000 of some implementations, a sealant (refer to 500 of FIG. 5) for sealing the memory chips 200 may be arranged on the base chip 100. For example, the sealant 500 may surround side surfaces of the memory chips 200 on the base chip 100 to seal the memory chips 200. The sealant 500 may not cover the top surface of the uppermost memory chip 200. Accordingly, the top surface of the uppermost memory chip 200 may be exposed from the sealant 500. However, in some implementations, the sealant 500 may cover the top surface of the uppermost memory chip 200.

The sealant 500 may include an insulating material, for example, a thermosetting resin such as an epoxy resin, a thermoplastic resin such as polyimide, or a resin including a reinforcing material such as an inorganic filler. For example, the sealant 500 may include an Ajinomoto build-up film (ABF), FR-4, or a Bismaleimide Triazine (BT) resin. In addition, the sealant 500 may include a molding material such as an epoxy molding compound (EMC) or a photosensitive material such as a photo-imageable encapsulant (PIE). However, the material of the sealant 500 is not limited to the above-described materials.

The semiconductor package 1000 of some implementations may have a structure in which the first memory chip 200-1 is stacked on the base chip 100 through HCB. Accordingly, the semiconductor package 1000 of the current implementation may reduce the thickness of the base chip 100 compared to a structure in which the first memory chip 200-1 is stacked on the base chip 100 through connection terminals. For example, the thickness of the first body layer 101 of Si constituting the base chip 100 may be 10 μm or less. The total thickness of the semiconductor package 1000 may be reduced through the thickness of the base chip 100.

More specifically, when stacking the first memory chip 200-1 on the base chip 100 in a wafer state through a TCB process using connection terminals, the first body layer 101 can have a thickness, for example, 50 μm or more, to prevent defects such as cracks in the base chip 100 under stress. However, in the case of the semiconductor package 1000 of some implementations, at least in part because the first memory chip 200-1 is stacked on the base chip 100 in a wafer state through HCB, the stress experienced by the base chip 100 is weak, and accordingly, the thickness of the first body layer 101 may be very small, for example, 10 μm or less. In addition, in the subsequent stacking process through the connection terminals of the memory chips 200, the base chip 100 and the first memory chip 200-1 may function as an integrated Si body.

FIGS. 3A, 3B, and 3C illustrate SAT photographs illustrating reliability tests when first memory chips are stacked on a base chip in a wafer state through HCB. The Si body layer of the wafer may have a thickness of about 10 μm. Specifically, FIG. 3A illustrates SAT photos for a temperature cycle (TC) test. The upper photo is an SAT photo for 18 chips, and the lower photo is an SAT photo for one chip. FIG. 3A illustrates that 18 chips have no defects over 1,000 cycles. FIG. 3B illustrates an SAT photo for a high accelerated stress test (HAST). The upper photo is an SAT photo for 34 chips, and the lower photo is an SAT photo for one chip. FIG. 3B illustrates that 34 chips have no defects over 264 hours. FIG. 3C illustrates SAT photos for a high temperature storage (HTS) test. The upper photo is an SAT photo for 29 chips, and the lower photo is an SAT photo for one chip. FIG. 3C illustrates that 29 chips have no defects over 1,000 hours. In conclusion, in the semiconductor package 1000 of some implementations, the thickness of the base chip 100 may be reduced, and accordingly, the total thickness of the semiconductor package 1000 may also be reduced.

In the semiconductor package 1000 of some implementations, at least in part because the first memory chip 200-1 is connected to the base chip 100 through HCB, high speed and high density input/output (I/O) may be implemented, and accordingly, high bandwidth can be more easily implemented. More specifically, when connecting the first memory chip 200-1 on the base chip 100 using a connection terminal, there is a limit to reducing a pitch of a pad due at least in part to restrictions on the size and pitch of the connection terminal. However, in the case of HCB, because pads are directly connected, it may be free from restrictions due to connection terminals, and thus, a fine pitch of the pad may be implemented. Implementation of such a fine pitch of the pad enables the implementation of high-density I/O, making it easier to implement high bandwidth.

For example, in FIG. 1A, the first upper pad 130u of the base chip 100 and the second lower pad 230d of the first memory chip 200-1 on which HCB is formed may have a first pitch P1. In contrast, the second upper pad 230u of the first memory chip 200-1 and the second pad 230 of the other memory chips 200 connected through the first connection terminal 260 may have a second pitch P2. Because HCB is a direct bond between pads, the first pitch P1 may be less than the second patch P2. Accordingly, the first upper pad 130u of the base chip 100 and the second lower pad 230d of the first memory chip 200-1 may implement a fine pitch due at least in part to HCB.

As shown in FIG. 2A, in the case of a semiconductor package COM of a comparative example, when a first core chip CC1 is stacked on a buffer chip BC or a buffer wafer BW through connection terminals SB such as solder bumps, the signal path becomes longer by the thickness THb of the connection terminal SB, which worsens signal processing. The signal processing typically worsens with more memory chips stacked. Referring to FIG. 2B, in some implementations, because the first memory chip 200-1 is directly connected to the base chip 100 through HCB, the signal path is shortened accordingly, which typically enables high-speed signal processing. As the number of memory chips stacked increases, the effect can increase.

The semiconductor package 1000 of some implementations have a structure in which the first memory chip 200-1 is stacked on the base chip 100 through HCB, thereby reducing the thickness of the entire package and reducing a region of a heterogeneous interface. For example, as shown in FIG. 2A, in the case of the semiconductor package COM of the comparative example, because the first core chip CC1 is stacked on the buffer chip BC or the buffer wafer BW through the connection terminal SB, the first thickness TH1, which is the total thickness of the semiconductor package COM of the comparative example, may include the thickness THb of the connection terminal SB. As shown in FIG. 2B, in the case of the semiconductor package 1000 of some implementations, because the first memory chip 200-1 is directly connected to the base chip 100 through HCB, the second thickness TH2, which is the total thickness of the semiconductor package 1000 of some implementations, may be less than the first thickness TH1 of the semiconductor package COM of the comparative example, by reducing the thickness THb of the connection terminal SB.

As described above, when stacking semiconductor chips through the connection terminal SB, an adhesive layer such as an NCF may be used. Accordingly, the heterogeneous interface region may be formed on the semiconductor chips by the adhesive layer. In the case of the semiconductor package 1000 of some implementations, at least in part because the first memory chip 200-1 is directly connected to the base chip 100 through HCB, the adhesive layer is reduced accordingly, and the heterogeneous interface region is reduced. Accordingly, warpage caused at least in part by a difference in thermal expansion rate may be reduced.

A 2.5D package structure used in high performance computing (HPC) enables high-speed communication between logic chips and memory chips through an interposer. In addition, the current trend in HPC is toward parallel computing, and for this purpose, high-speed communication with multiple memories is becoming more important. Therefore, the number of channels in the HBM package is gradually increasing, increasing a bandwidth. Increasing the bandwidth can be achieved by reducing the pitch of the connection pad. However, due at least in part to restrictions on the size and pitch of connection terminals such as bumps, there is a limit to reducing the pitch of the connection pad. However, in the case of the semiconductor package 1000 of the current implementation, because the first memory chip 200-1 is connected to the base chip 100 through HCB, the pitch of the pad may be reduced, thereby solving the above-mentioned problem.

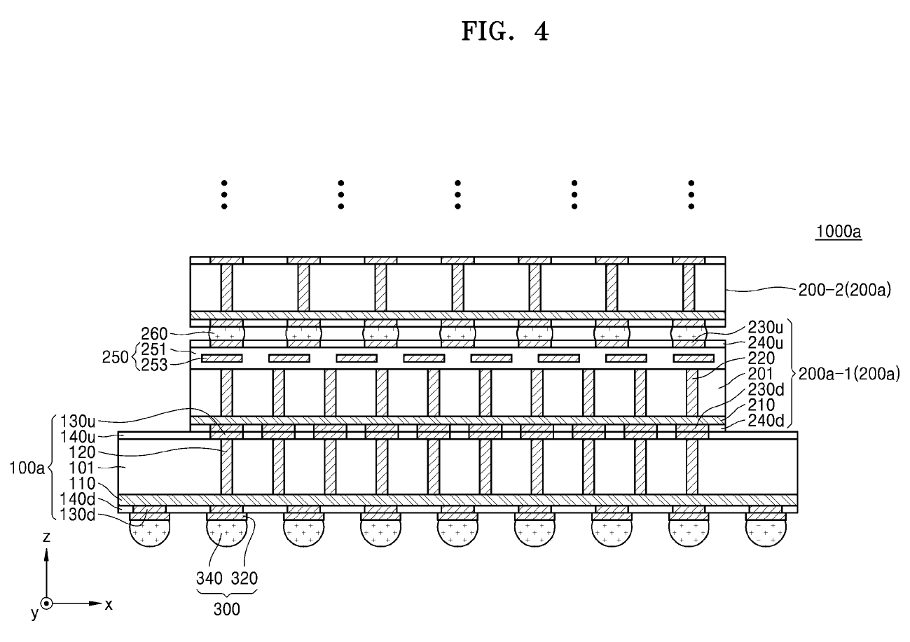

FIGS. 4 and 5 are cross-sectional views of semiconductor packages 1000a and 1000b according to implementations. Descriptions of features previously given in FIGS. 1A to 3C may be omitted.

Referring to FIG. 4, the semiconductor package 1000a of the current implementation may be different from the semiconductor package 1000 of FIG. 1A in structures of a base chip 100a and a first memory chip 200a-1. Specifically, the semiconductor package 1000a of the current implementation may include the base chip 100a, memory chips 200a, and external connection terminals 300. The semiconductor package 1000a of the current implementation may include, for example, an HBM package. However, the semiconductor package 1000a of the current implementation is not limited to the HBM package.

The base chip 100a may not include a first redistribution layer. Accordingly, the base chip 100a may include a first body layer 101, a first active layer 110, a first through electrode 120, a first pad 130, and a first protective layer 140. The base chip 100a may have a size greater than that of each of the memory chips 200a arranged thereon. However, the size of the base chip 100a is not limited thereto. For example, in some implementations, the base chip 100a may have substantially the same size as each of the memory chips 200a. The first body layer 101, the first active layer 110, and the first through electrode 120 are the same as described in the description of the base chip 100 of the semiconductor package 1000 of FIG. 1A.

The first pad 130 may include a first upper pad 130u and a first lower pad 130d. The first upper pad 130u may be arranged on a top surface of the first body layer 101. The first upper pad 130u may be connected to the first through electrode 120. In addition, the first upper pad 130u may be coupled to the second lower pad 230d of the first memory chip 200a-1 through HCB. The first lower pad 130d is the same as described in the description of the base chip 100 of the semiconductor package 1000 of FIG. 1A. In addition, the material of the first pad 130 is the same as in the description of the base chip 100 of the semiconductor package 1000 of FIG. 1A.

The first protective layer 140 may include a first upper protective layer 140u and a first lower protective layer 140d. The first upper protective layer 140u may be arranged on the top surface of the first body layer 101. The first upper pad 130u may be arranged through at least part of the first upper protective layer 140u. For example, the first upper pad 130u may be connected to the first through electrode 120 through at least part of the first upper protective layer 140u. The first lower protective layer 140d is the same as in the description of the base chip 100 of the semiconductor package 1000 of FIG. 1A. In addition, the material or layered structure of the first protective layer 140 is the same as in the description of the base chip 100 of the semiconductor package 1000 of FIG. 1A.

Except for a first memory chip 200a-1 among the memory chips 200a, the memory chips 200a thereon may be substantially the same as the memory chips 200 of the semiconductor package 1000 of FIG. 1A. In the semiconductor package 1000a of the current implementation, the first memory chip 200a-1 may be stacked on the base chip 100a through HCB. The first memory chip 200a-1 may include the second body layer 201, the second active layer 210, the second through electrode 220, the second pad 230, the second protective layer 240, and a second redistribution layer 250. The second body layer 201, the second active layer 210, and the second through electrode 220 are the same as in the description of the first memory chip 200-1 of the semiconductor package 1000 of FIG. 1A.

The second pad 230 may include a second upper pad 230u arranged on a top surface of the second redistribution layer 250 and a second lower pad 230d arranged on a bottom surface of the second active layer 210. The second upper pad 230u may be connected to a second redistribution line 253 of the second redistribution layer 250. In addition, the second upper pad 230u may be connected to the second through electrode 220 through the second redistribution line 253. In addition, the second lower pad 230d and the materials of the second pad 230 are the same as in the description of the first memory chip 200-1 of the semiconductor package 1000 of FIG. 1A.

The second protective layer 240 may include a second upper protective layer 240u arranged on the top surface of the second redistribution layer 250 and a second lower protective layer 240d arranged on the bottom surface of the second active layer 210. The second upper pad 230u may be arranged through at least part of the second upper protective layer 240u. For example, the second upper pad 230u may be connected to the second redistribution line 253 of the second redistribution layer 250 through at least part of the second upper protective layer 240u. In addition, the second lower protective layer 240d and the materials of the second protective layer 240 are the same as in the description of the first memory chip 200-1 of the semiconductor package 1000 of FIG. 1A.

The second redistribution layer 250 may be arranged on the second body layer 201. The second redistribution layer 250 may include a second redistribution body layer 251 and the second redistribution line 253. The materials or structures of the second redistribution body layer 251 and the second redistribution line 253 are the same as described for the first redistribution layer 150 of the base chip 100 of the semiconductor package 1000 of FIG. 1A.

In the first memory chip 200a-1 of the semiconductor package 1000a of the current implementation, the second redistribution layer 250 is arranged on the second body layer 201 so that the second through electrode 220 may be arranged without being restricted by a position of the second upper pad 230u. Accordingly, as illustrated in FIG. 4, the second through electrode 220 of the first memory chip 200a-1 and the second lower pad 230d connected thereto may be arranged with a fine pitch less than a pitch of the second upper pad 230u. In addition, the first upper pad 130u of the base chip 100a connected to the second lower pad 230d through HCB may also be arranged with a fine pitch. Although it is illustrated in FIG. 4 that a pitch of a second through electrode 220 of the first memory chip 200a-1 is equal to the pitch of the first through electrode 120 of the base chip 100a, the pitch of the second through electrode 220 may be different from the pitch of the first through electrode 120.

Furthermore, in the semiconductor package 1000a of the current implementation, the memory chips 200a above the first memory chip 200a-1 may be stacked on the memory chip 200a immediately below through first connection terminals 260. However, the memory chips 200a above the first memory chip 200a-1 are not limited to a stacked structure through the first connection terminals 260, and may be stacked on the memory chip 200a immediately below through HCB.

Referring to FIG. 5, the semiconductor package 1000b of the current implementation may be different from the semiconductor package 1000 of FIG. 1A in a structure of the base chip 100a. Specifically, the semiconductor package 1000b of the current implementation may include the base chip 100a, memory chips 200a, and external connection terminals 300. The semiconductor package 1000b of the current implementation may include, for example, an HBM package. However, the semiconductor package 1000b of the current implementation is not limited to the HBM package.

The base chip 100a may not include a first redistribution layer. Accordingly, the base chip 100a may include a first body layer 101, a first active layer 110, a first through electrode 120, a first pad 130, and a first protective layer 140. The base chip 100a may have a size greater than that of each of the memory chips 200 arranged thereon. However, the implementation is not limited thereto, and the base chip 100a may have substantially the same size as each of the memory chips 200. The base chip 100a is the same as in the description of the base chip 100a of the semiconductor package 1000a of FIG. 4.

In the semiconductor package 1000b of the current implementation, the memory chips 200 may be substantially the same as the memory chips 200 of the semiconductor package 1000 of FIG. 1A. Accordingly, the first memory chip 200-1 may not include a second redistribution layer. Among the memory chips 200, the first memory chip 200-1 may be stacked on the base chip 100a through HCB. In addition, the memory chips 200 above the first memory chip 200-1 may be stacked on the memory chip 200 immediately below through the first connection terminals 260. However, the memory chips 200 above the first memory chip 200-1 are not limited to a stacked structure through the first connection terminals 260, and may be stacked on the memory chip 200 immediately below through HCB.

In the base chip 100a of the semiconductor package 1000b according to the current implementation, the first through electrode 120 and the first upper pad 130u may be arranged with a pitch less than that of the second through electrode 220 of the first memory chip 200-1. In addition, the second lower pad 230d of the first memory chip 200-1 connected to the first upper pad 130u through HCB may also be arranged with a pitch less than that of the second through electrode 220. In the first memory chip 200-1 of the semiconductor package 1000b according to the current implementation, a pitch difference between the second through electrode 220 and the second lower pad 230d may be adjusted in the wiring layer of the second active layer 210.

In FIG. 5, the overall structure of the semiconductor package 1000b is illustrated, and the semiconductor packages 1000 and 1000a of FIGS. 1A and 4 may also have a similar structure. For example, the semiconductor packages 1000 and 1000a of FIGS. 1A and 4 can differ in terms of the structure of the base chip 100a and/or the first memory chip 200a-1, and the overall structure may be similar to the semiconductor package 1000b of FIG. 5.

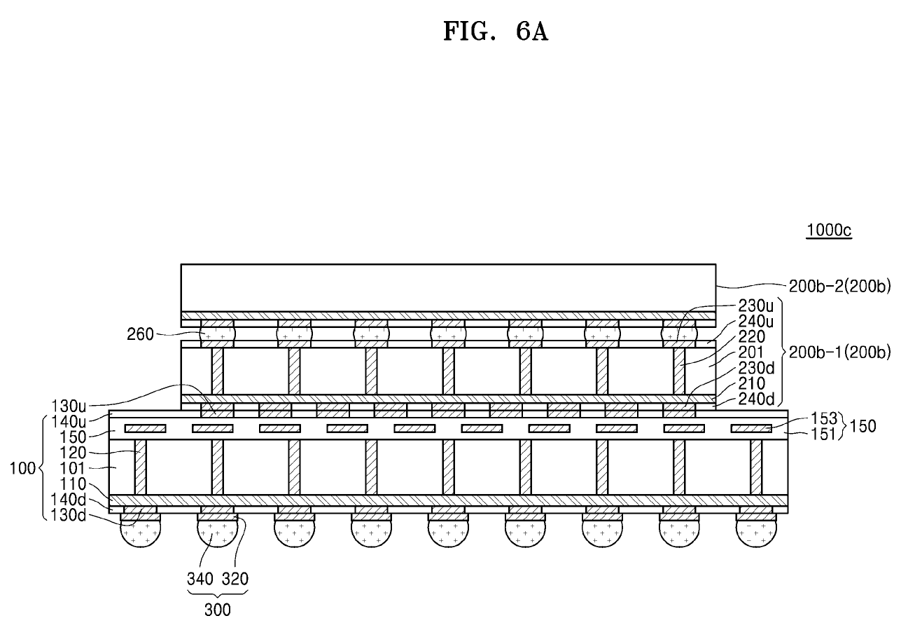

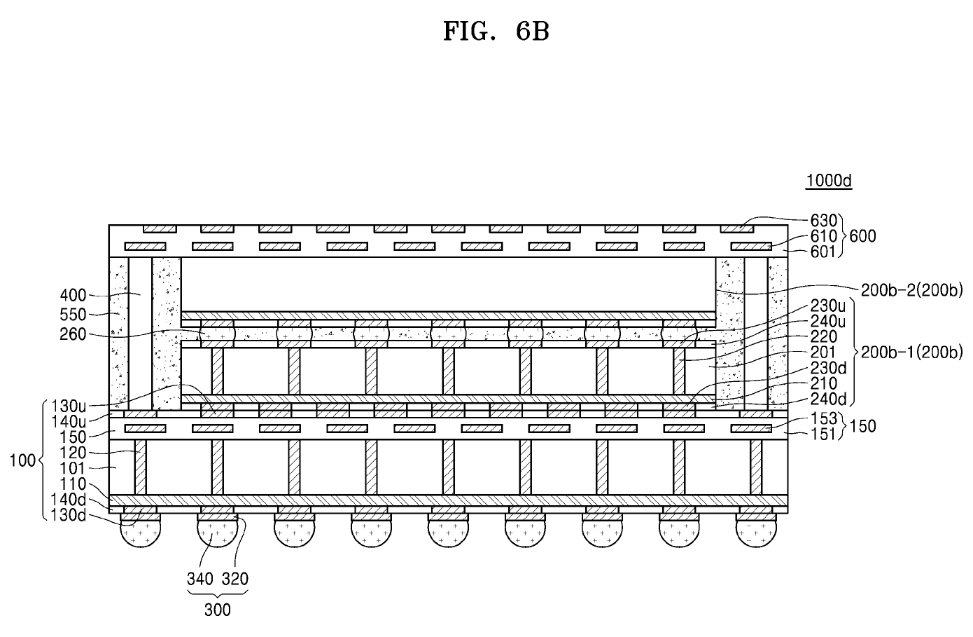

FIGS. 6A, 6B, and 6C are cross-sectional views of semiconductor packages 1000c to 1000e according to implementations. Descriptions of features previously given in FIGS. 1A to 5 may be omitted.

Referring to FIG. 6A, the semiconductor package 1000c of the current implementation may include a base chip 100, memory chips 200b, and external connection terminals 300. The base chip 100 and the external connection terminals 300 are the same as described for the base chip 100 and the external connection terminals 300 of the semiconductor package 1000 of FIG. 1A.

In the semiconductor package 1000b of the current implementation, the semiconductor chips 200b may include a first semiconductor chip 200b-1 and a second semiconductor chip 200b-2. The first semiconductor chip 200b-1 and the second semiconductor chip 200b-2 may both be memory chips, both logic chips, or one may include a logic chip and the other may include a memory chip. When both the first semiconductor chip 200b-1 and the second semiconductor chip 200b-2 are memory chips, the semiconductor package 1000b may be similar to the semiconductor package 1000 of FIG. 1A, differing in terms of the number of memory chips. As illustrated in FIG. 6A, the second semiconductor chip 200b-2 may not include the second through electrode 220.

When the semiconductor chip 200b includes a logic chip, the semiconductor chip 200b including the logic chip may be, for example, a modem chip supporting communication of the base chip 100. However, the type of the semiconductor chip 200b of the logic chip is not limited to the modem chip. For example, the semiconductor chip 200b of the logic chip may include various types of logic elements to support the operation of the base chip 100 or to perform various operations together with the base chip 100 or independently of the base chip 100.

In an example, the base chip 100, depending on its function, may include a central processing unit (CPU) chip, a micro-processor unit (MPU) chip, a graphics processing unit (GPU) chip, a neural processing unit (NPU) chip, a system on glass (SOG) chip, an application specific integrated circuit (ASIC) chip, a micro-processor chip, an application processor (AP) chip, or a controller chip. In addition, the semiconductor chip 200b of the logic chip may, for example, support communication or operation of the base chip 100, or may perform various operations together with the base chip 100 or independently of the base chip 100. In addition, depending on the type of the base chip 100, the semiconductor device including the semiconductor package 1000b of the current implementation may be classified into a server-oriented semiconductor device or a mobile-oriented semiconductor device.

In some implementations, when the semiconductor chip 200b includes the logic chip, the semiconductor chip 200b of the logic chip may perform a main operation such as the CPU chip, and the base chip 100 may support communication or operation of the semiconductor chip 200b of the logic chip such as the modem chip. In addition, in some implementations, both semiconductor chips 200b may include logic chips, and the base chip 100 may include an interposer chip mediating signal transmission. The base chip 100 of the interposer chip may include a controller controlling signal transmission. In addition, the base chip 100 of the interposer chip may include logic elements for operation and a PMIC managing power or clocks.

The semiconductor package 1000c according to the current implementation may have a three-dimensional (3D) package structure. In addition, in the semiconductor package 1000c of the current implementation, the first semiconductor chip 200b-1 may be stacked on the base chip 100 through HCB, and the second semiconductor chip 200b-2 may be stacked on the first semiconductor chip 200b-1 through the first connection terminals 260. Accordingly, the base chip 100 of the semiconductor package 1000c of the implementation may also be thinned, and thus the total thickness of the semiconductor package 1000c may be reduced. In addition, due at least in part to HCB between the base chip 100 and the first semiconductor chip 200b-1, fine pitches of pads may be implemented, and thus, a semiconductor package with high speed and high density I/O may be implemented.

Furthermore, in the semiconductor package 1000c of the current implementation, the second semiconductor chip 200b-2 may be stacked on the first semiconductor chip 200b-1 through the first connection terminals 260. However, the present disclosure is not limited thereto, and the second semiconductor chip 200b-2 may be stacked on the first semiconductor chip 200b-1 through HCB.

In addition, in the semiconductor package 1000c according to the current implementation, three or more semiconductor chips 200b may be stacked on the base chip 100, and at least one of the semiconductor chips 200b may include a logic chip. In such a structure, the semiconductor chips 200b above the first semiconductor chip 200b-1 may be stacked on the semiconductor chip 200b immediately below through the first connection terminals 260 or HCB.

Referring to FIG. 6B, the semiconductor package 1000d of the current implementation may be different from the semiconductor package 1000c of FIG. 6A in that the semiconductor package 1000d further includes a through post 400 and a redistribution substrate 600. Specifically, the semiconductor package 1000d of the current implementation may include a base chip 100, semiconductor chips 200b, external connection terminals 300, the through post 400, and the redistribution substrate 600. The base chip 100, the semiconductor chips 200b, and the external connection terminals 300 are the same as in the description of the semiconductor package 1000c of FIG. 6A.

The through post 400 may be arranged between the base chip 100 and the redistribution substrate 600. As a lower sealant 550 is arranged between the base chip 100 and the redistribution substrate 600, the through post 400 may extend through the lower sealant 550. The through post 400 may electrically connect the base chip 100 to the redistribution substrate 600. For example, a bottom surface of the through post 400 may be connected to the first upper pad 130u of the base chip 100, and a top surface of the through post 400 may be connected to a redistribution line 6μof the redistribution substrate 600.

The through post 400 may include Cu. Accordingly, the through post 400 may be referred to as a Cu post. However, the material of the through post 400 is not limited to Cu. The through post 400 may be formed through, for example, electro-plating.

The redistribution substrate 600 may be arranged on the semiconductor chips 200b, the through post 400, and the lower sealant 550. The redistribution substrate 600 may have a structure similar to that of the first redistribution layer 150 of the base chip 100. For example, the redistribution substrate 600 may include a redistribution body layer 601, the redistribution line 610, and a redistribution pad 630. The redistribution body layer 601 and the redistribution line 610 are the same as described for the first redistribution body layer 151 and the first redistribution line 153 of the base chip 100. The redistribution pad 630 may be arranged on a top surface of the redistribution substrate 600. For example, the redistribution pad 630 may be arranged in a structure in which at least part of the redistribution pad 630 is buried in an upper portion of the redistribution body layer 601.

In addition, the lower sealant 550 may be arranged between the base chip 100 and the redistribution substrate 600. The lower sealant 550 may cover and seal side surfaces of the semiconductor chips 200b and the through post 400. In addition, as illustrated in FIG. 6B, the lower sealant 550 may be filled between the first semiconductor chip 200b-1 and the second semiconductor chip 200b-2, and among the first connection terminals 260 on a bottom surface of the second semiconductor chip 200b-2. However, in some implementations, an adhesive layer or underfill is filled between the first semiconductor chip 200b-1 and the second semiconductor chip 200b-2, and the lower sealant 550 may cover side surfaces of the adhesive layer or underfill. The material of the lower sealant 550 is the same as described for the sealant 500 of the semiconductor package 1000 of FIG. 1A.

Referring to FIG. 6C, the semiconductor package 1000e of the current implementation may be different from the semiconductor package 1000d of FIG. 6B in that the semiconductor package 1000e further includes a semiconductor device 700. Specifically, the semiconductor package 1000e of the current implementation may include a base chip 100, semiconductor chips 200b, external connection terminals 300, the through post 400, the redistribution substrate 600, and the semiconductor device 700. The base chip 100, the semiconductor chips 200b, the external connection terminals 300, the through post 400, and the redistribution substrate 600 are the same as in the description of the semiconductor package 1000d of FIG. 6B.

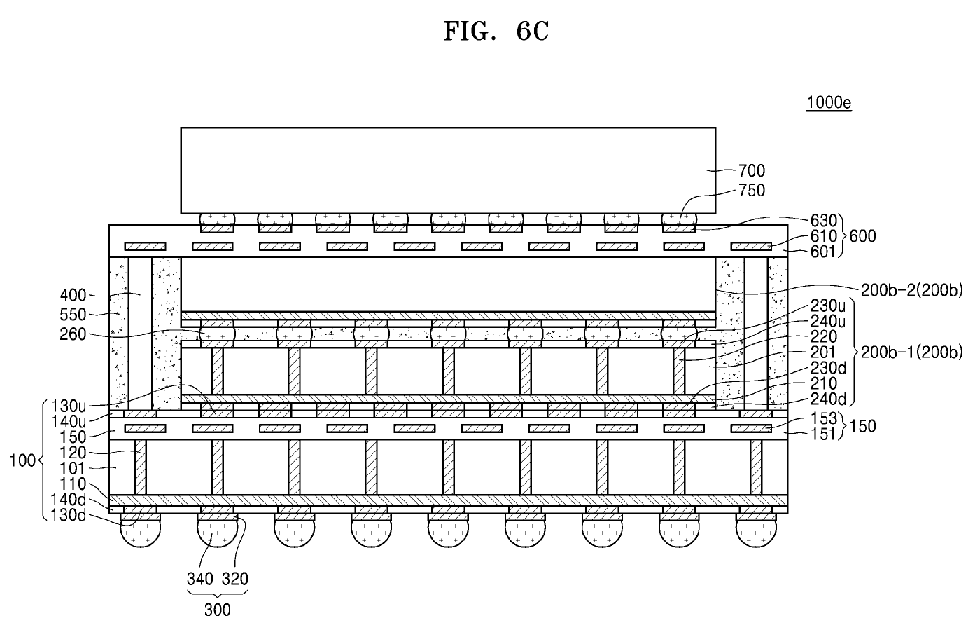

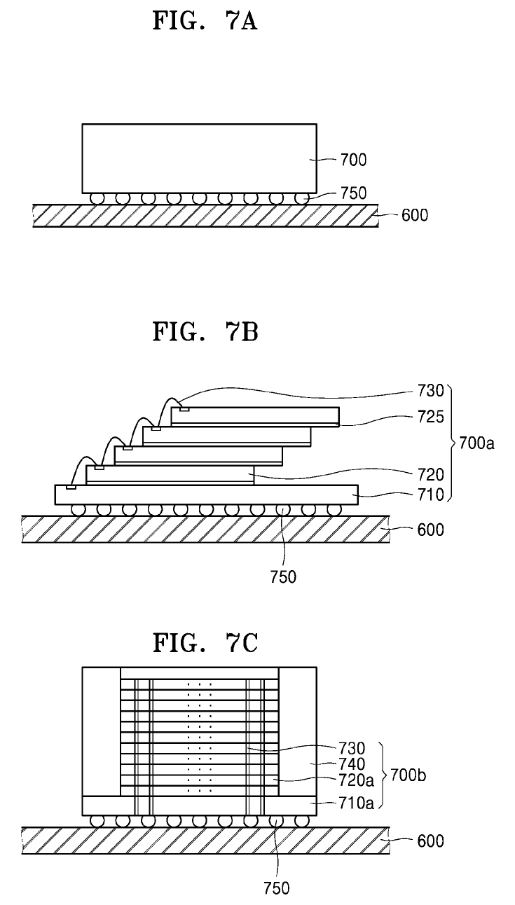

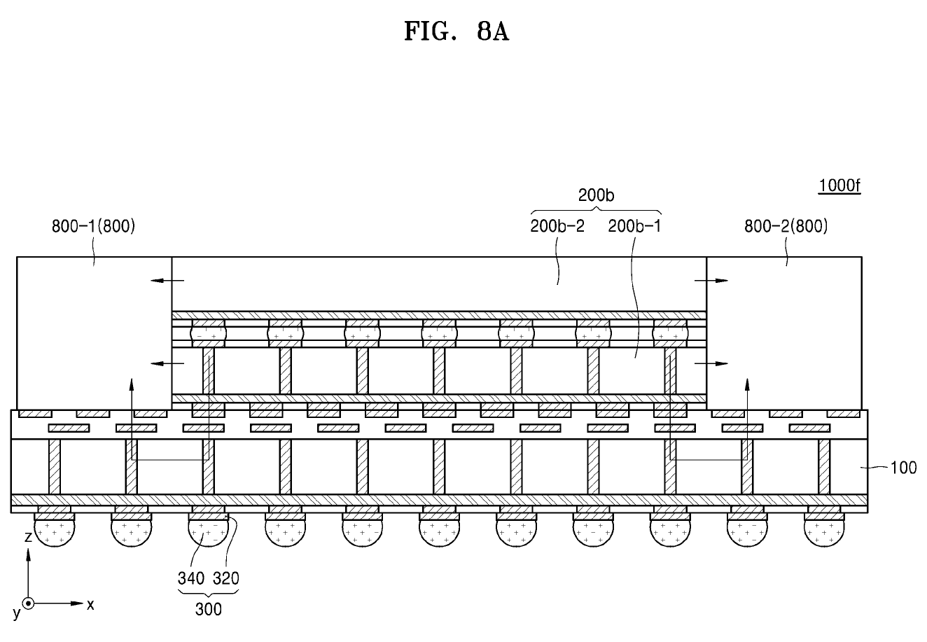

The semiconductor device 700 may be mounted on the redistribution substrate 600 through second connection terminals 750. The semiconductor device 700 may include a single chip or a package including a plurality of chips. For example, when the semiconductor device 700 includes the single chip, the semiconductor device 700 may include one memory chip. When the semiconductor device 700 includes the package, the semiconductor device 700 may include, for example, a plurality of memory chips. The single chip structure and package structure of the semiconductor device 700 will be described in more detail with reference to FIGS. 7A to 7C.

When the semiconductor device 700 includes the memory chip, the semiconductor device 700 may include, for example, a volatile memory device such as DRAM or SRAM, or a non-volatile memory device such as flash memory, electrically erasable programmable read only memory (EEPROM), PRAM, MRAM, FeRAM, or RRAM. In the semiconductor package 1000e of the current implementation, the semiconductor device 700 may include, for example, a DRAM chip. However, the semiconductor device 700 is not limited to the DRAM chip.

When the semiconductor device 700 includes the package, the semiconductor package 1000e of the current implementation may correspond to a package on package (POP) structure. For example, in the semiconductor package 1000e of the current implementation, the base chip 100, the semiconductor chips 200b, the through post 400, and the redistribution substrate 600 may constitute a lower package, and the semiconductor device 700 of the package structure may constitute an upper package. Accordingly, the semiconductor package 1000e of the current implementation may have a POP structure in which the upper package is stacked on the lower package.

FIGS. 7A, 7B, and 7C are cross-sectional views illustrating the structure of the semiconductor device 700 in the semiconductor package 1000e of FIG. 6C in more detail. Descriptions of features previously given in FIGS. 1A to 6C may be omitted.

Referring to FIG. 7A, in the semiconductor package 1000e of FIG. 6C, the semiconductor device 700 may include one memory chip. The memory chip may include, for example, a volatile memory device such as DRAM or SRAM, or a non-volatile memory device such as flash memory. In the semiconductor package 1000e of the current implementation, the semiconductor device 700 may include, for example, a DRAM chip. The semiconductor device 700 may be mounted on the redistribution substrate 600 through second connection terminals 750.

Referring to FIG. 7B, in the semiconductor package 1000e of FIG. 6C, a semiconductor device 700a may include a semiconductor package having a wire bonding structure. Specifically, the semiconductor device 700a may include a package substrate 710 and memory chips 720 stacked on the package substrate 710. The memory chips 720 may be mounted on the package substrate 710 in a wire bonding structure using an adhesive layer 725 and a wire 730. The memory chip 720 of the semiconductor device 700a may include, for example, a volatile memory device such as DRAM or SRAM, or a non-volatile memory device such as flash memory. In the semiconductor package 1000e of the current implementation, the memory chip 720 of the semiconductor device 700a may include, for example, a DRAM chip. In addition, the semiconductor device 700a may include an internal sealant for sealing the memory chips 720 and the wire 735 on the package substrate 710. However, in FIG. 7B, the internal sealant is omitted for convenience.

In FIG. 7B, four memory chips 720 are stacked on the package substrate 710, but the number of memory chips 720 is not limited to four. For example, three or less memory chips 720 or five or more memory chips 720 may be stacked on the package substrate 710. In addition, without being limited to a step structure, the memory chip 720 may be stacked on the package substrate 710 in a zigzag structure or a combination of the step structure and the zigzag structure. The second connection terminals 750 may be arranged on a bottom surface of the package substrate 710. Accordingly, the semiconductor device 700a of the package structure may also be mounted on the redistribution substrate 600 through the second connection terminals 750.

Referring to FIG. 7C, in the semiconductor package 1000e of FIG. 6C, the semiconductor device 700b may include an HBM package. Specifically, the semiconductor device 700b may include a buffer chip 710a, a plurality of core chips 720a stacked on the buffer chip 710a, and an internal sealant 740. In addition, the buffer chip 710a and the plurality of core chips 720a may include a through electrode 730 therein. However, the uppermost core chip 720a among the plurality of core chips 720a may not include the through electrode 730.

The buffer chip 710a may include logic elements. Accordingly, the buffer chip 710a may include a logic chip. The buffer chip 710a arranged under the core chips 720a may integrate signals from the core chips 720a to transmit the signals to the outside and may also transmit signals and power from the outside to the core chips 720a. Accordingly, the buffer chip 710a may be referred to as a control chip.

Each of the plurality of core chips 720a may include a memory chip. For example, each of the plurality of core chips 720a may include a DRAM chip. Meanwhile, a core chip 720a may be stacked on the buffer chip 710a or a core chip 720a below through pad-to-pad bonding, HCB, bonding using connection terminals, or bonding using an anisotropic conductive film (ACF). Here, the ACF is an anisotropic conductive film that conducts electricity in only one direction, and may refer to a conductive film made in a film state by mixing fine conductive particles with an adhesive resin.

In FIG. 7C, eight core chips 720a are stacked on the buffer chip 710a, but the number of core chips 720a is not limited to eight. For example, seven or less or nine or more core chips 720a may be stacked on the buffer chip 710a.

The core chips 720a on the buffer chip 710a may be sealed by the internal sealant 740. However, a top surface of the uppermost core chip 720a among the core chips 720a may not be covered with the internal sealant 740. However, in other implementations, the top surface of the uppermost core chip 720a may be covered with the internal sealant 740. The second connection terminals 750 may be arranged on a bottom surface of the buffer chip 710a. Accordingly, the semiconductor device 700b of the HBM package may also be mounted on the redistribution substrate 600 through the second connection terminals 750.

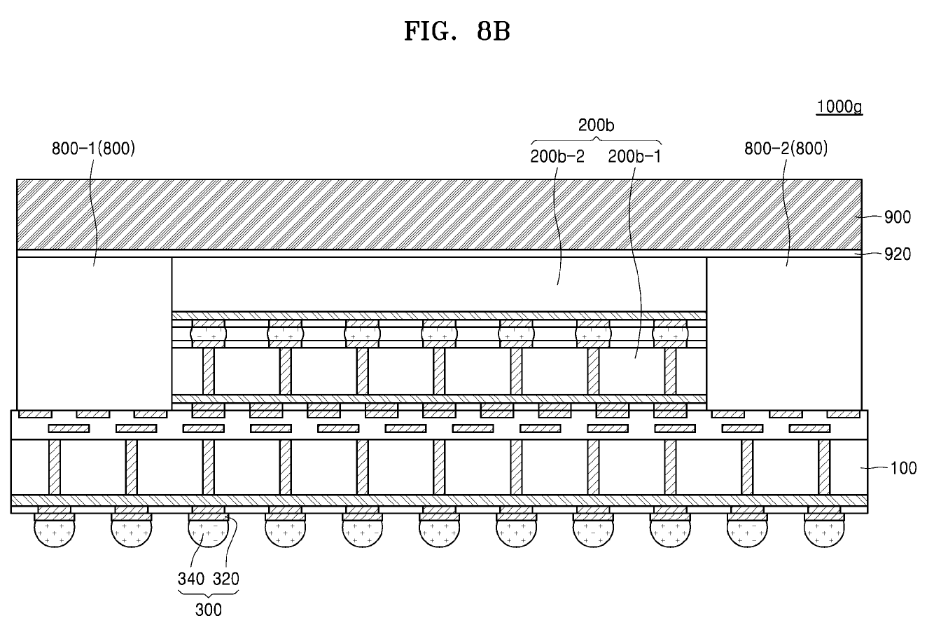

FIGS. 8A and 8B are cross-sectional views of semiconductor packages 1000f and 1000g according to implementations. Descriptions of features previously given in FIGS. 1A to 7C may be omitted.

Referring to FIG. 8A, the semiconductor package 1000f of the current implementation may be different from the semiconductor package 1000c of FIG. 6A in that the semiconductor package 1000f further includes a dummy Si chip 800. Specifically, the semiconductor package 1000f of the current implementation may include a base chip 100, semiconductor chips 200b, external connection terminals 300, and the dummy Si chip 800. The base chip 100, the semiconductor chips 200b, and the external connection terminals 300 are the same as those described in the description of the semiconductor package 1000c of FIG. 6A.

The dummy Si chip 800 may include a first dummy Si chip 800-1 and a second dummy Si chip 800-2. For example, the first dummy Si chip 800-1 may be arranged on the base chip 100 on the left side of the semiconductor chip 200b in an x direction, and the second dummy Si chip 800-2 may be arranged on the base chip 100 on the right side of the semiconductor chip 200b in the x direction. In some implementations, there is one dummy Si chip 800 and may be arranged on either base chip 100 of the semiconductor chip 200b in the x direction.

The dummy Si chip 800 may be a heat dissipation chip, and accordingly, no elements or wires may be formed therein. In general, thermal conductivity of Si may be higher than that of a resin constituting the sealant, for example, an EMC. Accordingly, the dummy Si chip 800 may contribute to efficiently dissipating heat generated by the base chip 100 and the semiconductor chips 200b, as illustrated by the arrows in FIG. 8A.

Referring to FIG. 8B, the semiconductor package 1000g of the current implementation may be different from the semiconductor package 1000f of FIG. 8A in that the semiconductor package 1000g further includes a heat dissipation structure 900. Specifically, the semiconductor package 1000g of the current implementation may include a base chip 100, semiconductor chips 200b, external connection terminals 300, the dummy Si chip 800, and the heat dissipation structure 900. The base chip 100, the semiconductor chips 200b, the external connection terminals 300, and the dummy Si chip 800 are the same as in the description of the semiconductor package 1000f of FIG. 8A.

The heat dissipation structure 900 may be stacked on the semiconductor chips 200b and the dummy Si chip 800 through an adhesive layer 920. The heat dissipation structure 900 may include, for example, a heatsink or a heatslug. In some implementations, the heat dissipation structure 900 may be referred to as a heat path block (HPB). The adhesive layer 920 may include a material with high thermal conductivity. For example, the adhesive layer 920 may include a thermal interface material (TIM) or a thermally conductive resin. The TIM may include a material with high thermal conductivity, e.g., low thermal resistance materials, such as grease, a tape, an elastomer filling pad, or a phase change material.

FIGS. 9A to 9E are cross-sectional views schematically illustrating processes of a semiconductor package manufacturing method according to an implementation. Description is given with reference to FIGS. 1A and 1B together and descriptions of features previously given in FIGS. 1A to 8B may be omitted.

Referring to FIG. 9A, in the semiconductor package manufacturing method of the current implementation, first, external connection terminals 300 are formed on a first initial base substrate 100Sa. The first initial base substrate 100Sa may include a plurality of initial base chips. Accordingly, the first initial base substrate 100Sa may include a first initial body layer 101a, a first active layer 110, a first through electrode 120, a first lower pad 130d, and a first lower protective layer 140d. Here, the first initial base substrate 100Wa, before the grinding process is performed, may be thicker than the second initial base substrate 100Sb after the grinding process. In the first initial base substrate 100Sa, the bottom surface of the first through electrode 120 may not be exposed.

Each of the external connection terminals 300 may be arranged on a chip pad on the first active layer 110, for example, the first lower pad 130d. When forming the external connection terminals 300, the first initial base substrate 100Sa may be fixed onto a first carrier substrate through an adhesive layer. The external connection terminals 300 are the same as described for the external connection terminals 300 of the semiconductor package 1000 of FIG. 1A.

Referring to FIG. 9B, after forming the external connection terminals 300, a rear portion of the first initial base substrate 100Sa is removed by a grinding process and an etching process to form a second initial base substrate 100Sb. The second initial base substrate 100Sb may include a plurality of initial base chips. After the grinding process and the etching process, the first through electrode 120 may be exposed. Although not shown, a protective layer may be formed on a rear surface of the second initial base substrate 100Sb. The first through electrode 120 may be exposed from the protective layer through the protective layer. In addition, the grinding process and the etching process may be performed after separating the first initial base substrate 100Sa from the first carrier substrate and bonding a surface of the first initial base substrate 100Sa on which the external connection terminals 300 are arranged to a second carrier substrate through the adhesive layer.

Referring to FIG. 9C, after forming the second initial base substrate 100Sb, a first initial redistribution layer 150a is formed on the rear surface of the second initial base substrate 100Sb. The first initial redistribution layer 150a may have a wafer-level size corresponding to the second initial base substrate 100Sb. Except for the size, the first initial redistribution layer 150a is the same as described for the first redistribution layer 150 of the semiconductor package 1000 of FIG. 1A. The base substrate 100S may be formed through the formation of the first initial redistribution layer 150a. The base substrate 100S may include a plurality of base chips 100.

Referring to FIG. 9D, after forming the base substrate 100S, the first memory chip 200-1 is mounted on the first initial redistribution layer 150a. The first memory chip 200-1 may be arranged at a position corresponding to the base chip 100 of the base substrate 100S. Accordingly, a plurality of first memory chips 200-1 may be mounted on the first initial redistribution layer 150a to correspond to the plurality of base chips 100 of the base substrate 100S. The first memory chip 200-1 may be mounted on the first initial redistribution layer 150a through HCB. Specifically, the second lower pad 230d of the first memory chip 200-1 may be coupled to the first upper pad 130u of the base chip 100, and the second lower protective layer 240d of the first memory chip 200-1 may be coupled to the first upper protective layer 140u of the base chip 100.

In the process of stacking the first memory chip 200-1 on the first initial redistribution layer 150a through HCB, the base substrate 100S and the first memory chip 200-1 are subjected to plasma treatment and ultrapure water cleaning before bonding to form a hydroxide (OH) dangling bond on the first upper protective layer 140u of the base substrate 100S and the second lower protective layer 240d of the first memory chip 200-1. Thereafter, the first memory chip 200-1 is bonded to the base substrate 100S so that the second lower pad 230d of the first memory chip 200-1 is aligned with the first upper pad 130u of the base substrate 100S at room temperature. At the initial stage of bonding, OH dangling bonds of the first upper protective layer 140u of the base substrate 100S and the second lower protective layer 240d of the first memory chip 200-1 may form hydrogen bonding. Hydrogen bonding may have relatively low bonding strengths.

Thereafter, as heat is applied through annealing, a tight bonding structure may be formed between the first upper pad 130u of the base substrate 100S and the second lower pad 230d of the first memory chip 200-1. Specifically, a metal expansion process and a metal diffusion process may occur in the first upper pad 130u of the base substrate 100S and the second lower pad 230d of the first memory chip 200-1 through the heat treatment, and the first upper pad 130u of the base substrate 100S and the second lower pad 230d of the first memory chip 200-1 may be integrated through the metal expansion and diffusion process. Meanwhile, hydrogen bonding between the first upper protective layer 140u of the initial base substrate 100S and the second lower protective layer 240d of the first memory chip 200-1 is changed to oxide bonding through heat treatment. For example, simply expressed in chemical formula, -OH + -OH --> O + H₂O through high-temperature heat treatment. Oxide bonding may have higher bonding strength than hydrogen bonding. As a result, the first memory chip 200-1 may be firmly coupled to the base substrate 100S through HCB with high bonding force.

Referring to FIG. 9E, after stacking the first memory chip 200-1, the second memory chip 200-2 is stacked on the first memory chip 200-1 through a TCB process using the first connection terminals 260 and the adhesive layer 270. Subsequently, the same process is performed to stack a plurality of memory chips 200 on the first memory chip 200-1.

Thereafter, the base substrate 100S and the structure on the base substrate 100S are separated from the second carrier substrate and individualized through a sawing process in a ring mount device, thereby completing the semiconductor package 1000. The semiconductor package 1000 may correspond to the semiconductor package 1000 of FIG. 1A. In addition, although not shown, a sealant 500 that seals the memory chips 200 may be formed on the base substrate 100W before individualization through the sawing process. Accordingly, the sealant 500 is also individualized in the sawing process, and the sealant 500 may be included in the semiconductor package 1000.

As used herein, the term “at least one of” or “at least one selected from” can refer and encompass any and all possible combinations of one or more of the associated listed terms. For example, the term "at least one of A, B, or C" means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a logic chip;
a first memory chip arranged on the logic chip with a size less than that of the logic chip, wherein the first memory chip is stacked, along a first direction, on the logic chip through hybrid copper bonding; and
at least one second memory chip stacked, along the first direction, on the first memory chip.

2. The semiconductor package of claim 1, wherein the logic chip comprises a redistribution layer.

3. The semiconductor package of claim 2, wherein the redistribution layer extends, along a second direction, beyond an edge of the first memory chip, wherein the second direction is orthogonal to the first direction.

4. The semiconductor package of claim 2,
wherein the logic chip comprises a plurality of through electrodes connected to the redistribution layer, and
wherein at least one through electrode of the plurality of through electrodes is in a first area outside of a footprint of the first memory chip and the at least one second memory chip and at least one additional through electrode of the plurality of through electrodes is in a second area overlapped by the first memory chip and the at least one second memory chip.

5. The semiconductor package of claim 2,
wherein the logic chip comprises a protective layer on the redistribution layer, and
wherein the protective layer comprises a planar top surface.

6. The semiconductor package of claim 1, comprising a connection terminal between the second memory chip and the first memory chip.

7. The semiconductor package of claim 1,
wherein the logic chip comprises a plurality of first chip pads and the first memory chip comprises a plurality of second chip pads, and wherein the plurality of first chip pads are coupled to the plurality of second chip pads through the hybrid copper bonding, and
wherein the at least one second memory chip comprises a plurality of third chip pads, and a pitch between adjacent second chip pads of the plurality of second chip pads is less than a pitch between adjacent the third chip pads of the plurality of third chip pads.

8. The semiconductor package of claim 1,
wherein the first memory chip and the at least one second memory chip comprise dynamic random access memory chips, and
wherein the semiconductor package comprises a high bandwidth memory package.

9. The semiconductor package of claim 1,
wherein the logic chip comprises a silicon body layer, and
wherein a thickness of the silicon body layer is 10 μm or less.

10. A semiconductor package comprising:
a first semiconductor chip comprising a plurality of first chip pads;
a second semiconductor chip comprising a plurality of second chip pads, wherein the second semiconductor chip is smaller in size than the first semiconductor chip, wherein the second semiconductor chip is stacked, along a first direction, on the first semiconductor chip, and wherein the second chip pad is coupled to the first chip pad through hybrid copper bonding; and
a third semiconductor chip comprising a plurality of third chip pads, wherein the third semiconductor chip is stacked, along the first direction, on the second semiconductor chip through a connection terminal on the third chip pad,
wherein a pitch between adjacent second chip pads of the plurality of second chip pads is less than a pitch between adjacent third chip pads of the plurality of third chip pads.

11. The semiconductor package of claim 10,
wherein the first semiconductor chip comprises a logic chip,
wherein each of the second semiconductor chip and the third semiconductor chip comprises a respective memory chip, and
wherein at least one additional memory chip is arranged on the third semiconductor chip.

12. The semiconductor package of claim 10,
wherein the first semiconductor chip comprises a redistribution layer and a plurality of through electrodes connected to the redistribution layer, and
wherein the plurality of through electrodes extend along a second direction, beyond an edge of the second semiconductor chip, wherein the second direction is orthogonal to the first direction.

13. The semiconductor package of claim 10, further comprising:
a through post separate from the second semiconductor chip and on an outer portion of the first semiconductor chip; and
a redistribution substrate on the third semiconductor chip and the through post,
wherein the first semiconductor chip comprises an interposer chip, and
wherein each of the second semiconductor chip and the third semiconductor chip comprises a respective logic chip.

14. The semiconductor package of claim 13, comprising a semiconductor device on the redistribution substrate, wherein the semiconductor device comprises a memory chip.

15. The semiconductor package of claim 10, comprising a dummy silicon chip on an outer portion of the first semiconductor chip and adjacent to the second semiconductor chip.

16. A semiconductor package comprising:
a base chip comprising a plurality of first chip pads and a first protective layer;
a first semiconductor chip comprising a plurality of second chip pads and a second protective layer, wherein the first semiconductor chip is stacked, along a first direction, on the base chip, and wherein a size of the first semiconductor chip is smaller than a size of the base chip; and
a second semiconductor chip comprising a plurality of third chip pads, wherein the second semiconductor chip is stacked, along the first direction, on the first semiconductor chip through a connection terminal, wherein the second semiconductor chip comprises a size that is substantially the same as the size of the first semiconductor chip,
wherein the plurality of first chip pads and the first protective layer are coupled to the plurality of second chip pads and the second protective layer, respectively, through hybrid copper bonding, and
wherein a pitch between adjacent second chip pads of the plurality of second chip pads is less than a pitch between adjacent third chip pads of the plurality of third chip pads.

17. The semiconductor package of claim 16, further comprising:
at least one memory chip stacked on the second semiconductor chip through an additional connection terminal; and
a sealant sealing the first semiconductor chip, the second semiconductor chip, and the at least one memory chip on the base chip,
wherein the base chip comprises a logic chip, and
wherein each of the first semiconductor chip and the second semiconductor chip comprise a respective memory chip.

18. The semiconductor package of claim 16,
wherein the base chip comprises an upper redistribution layer and a plurality of through electrodes connected to the upper redistribution layer, and
wherein the plurality of through electrodes extends along a second direction, beyond an edge of the first semiconductor chip, wherein the second direction is orthogonal to the first direction.

19. The semiconductor package of claim 16, comprising:
a through post separate from the first semiconductor chip and on an outer portion of the base chip;
a redistribution substrate on the second semiconductor chip and the through post; and
a semiconductor device arranged on the redistribution substrate.

20. The semiconductor package of claim 16, comprising a dummy silicon chip on an outer portion of the base chip and adjacent to the first semiconductor chip.
